(19) United States
(12) Patent Application Publication
(10) Pub. No.: US 2026/0282407 A1
(43) Pub. Date: Sep. 17, 2026

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Noritsugu NOMURA, Tokyo (JP); Yosuke NAKANISHI, Tokyo (JP); Koji TANAKA, Tokyo (JP); Reona FURUKAWA, Tokyo (JP); Takashi FUJIMOTO, Tokyo (JP)

(73) Assignee: Mitsubishi Electric Corporation, Tokyo (JP)

(21) Appl. No.: 19/414,406

(22) Filed: Dec. 10, 2025

(30) Foreign Application Priority Data
Mar. 14, 2025 (JP) 2025-041067

(51) Int. Cl. H10D 12/00; H10D 12/01

(52) U.S. Cl. CPC H10D 12/416; H10D 12/038; H10D 12/481

(57) ABSTRACT

A semiconductor device according to the present disclosure includes a semiconductor substrate having an upper surface and a rear surface, a trench being formed in the upper surface; a first gate electrode provided inside the trench; a first insulating film provided between the first gate electrode and a sidewall of the trench; a second gate electrode provided on the first gate electrode inside the trench; a second insulating film provided between the second gate electrode and the sidewall of the trench; and a third insulating film separating the first gate electrode and the second gate electrode, wherein the first insulating film includes an outer insulating film in contact with the semiconductor substrate, and an inner insulating film in contact with the first gate electrode, and a density of interface states of the inner insulating film is higher than a density of interface states of the outer insulating film.

### BACKGROUND

### Field

The present disclosure relates to a semiconductor device and a method for manufacturing the semiconductor device.

### Background

JP 2019-12813 A discloses an IGBT (Insulated Gate Bipolar Transistor) with a low on-voltage and reduced switching loss. This IGBT sequentially comprises a first semiconductor layer of a first conductivity type, a second semiconductor layer of a second conductivity type, a third semiconductor layer of the second conductivity type, a fourth semiconductor layer of the first conductivity type, and a fifth semiconductor layer of the second conductivity type, on a first electrode between the first electrode and a second electrode. An third electrode is provided on the third semiconductor layer, the fourth semiconductor layer, and the fifth semiconductor layer with a gate insulating film interposed therebetween, and is insulated from the first electrode and the second electrode. A fourth electrode is provided between the third electrode and the second semiconductor layer, and is insulated from the third electrode and the second semiconductor layer.

A power semiconductor device has its current turned on and off by the potential of a gate electrode, and is generally used as a switch. Therefore, it is desired that the on-resistance is low and the switching speed is high. In trench gate power semiconductor devices, the on-resistance has been reduced by miniaturizing cells. In recent years, a double trench gate structure has been proposed in order to further reduce the on-resistance. The double trench gate structure has a thin gate oxide film inside the trench, and a further inner portion, for example, polysilicon, is divided into two parts, upper and lower, by an insulator.

In the double trench gate structure as shown in JP 2019-12813 A, by adjusting the thickness of the gate oxide film, it is possible to control the gate-collector capacitance and realize a power semiconductor device with a low on-resistance and a high switching speed. However, when the gate oxide film is formed by thermal oxidation, warpage may occur in the power semiconductor device due to the thermal history of the manufacturing process, especially when the insulating film formed on the side surface of the lower gate electrode is formed thick. At this time, when the power semiconductor device is mounted on the module, a gap may be generated between a module substrate and the power semiconductor device, which may cause quality deterioration such as a decrease in short-circuit withstand capability.

### SUMMARY

The present disclosure has been made to solve the above-mentioned problem, and aims to provide a semiconductor device capable of suppressing warpage and a method for manufacturing the semiconductor device.

The features and advantages of the present disclosure may be summarized as follows.

According to an aspect of the present disclosure, a semiconductor device includes a semiconductor substrate having an upper surface and a rear surface opposite to the upper surface, a trench being formed in the upper surface; a first main electrode provided on the upper surface of the semiconductor substrate; a second main electrode provided on the rear surface of the semiconductor substrate; a first gate electrode provided inside the trench; a first insulating film provided between the first gate electrode and a sidewall of the trench in a direction parallel to the upper surface of the semiconductor substrate; a second gate electrode provided on the first gate electrode inside the trench; a second insulating film provided between the second gate electrode and the sidewall of the trench in the direction parallel to the upper surface of the semiconductor substrate; and a third insulating film separating the first gate electrode and the second gate electrode in a direction from the upper surface to the rear surface of the semiconductor substrate, wherein the first insulating film includes an outer insulating film in contact with the semiconductor substrate, and an inner insulating film in contact with the first gate electrode, and a density of interface states of the inner insulating film is higher than a density of interface states of the outer insulating film.

According to an aspect of the present disclosure, a method for manufacturing a semiconductor device includes forming a trench in an upper surface of a semiconductor substrate having the upper surface and a rear surface opposite to the upper surface; forming an outer insulating film on an inner wall of the trench by thermal oxidation; forming an inner insulating film on the outer insulating film by chemical vapor deposition at 500° C. or less inside the trench; forming a first gate electrode in the trench such that the first gate electrode is separated from the inner wall of the trench by a first insulating film including the outer insulating film and the inner insulating film; after removing a portion of the first insulating film and a portion of the first gate electrode on an upper side of the trench, forming a second insulating film on the inner wall of the trench above the first insulating film and forming a third insulating film on the first gate electrode; forming a second gate electrode on the third insulating film inside the trench such that the second gate electrode is separated from the inner wall of the trench by the second insulating film; forming a first main electrode on the upper surface of the semiconductor substrate; and forming a second main electrode on the rear surface of the semiconductor substrate.

Other and further objects, features and advantages of the disclosure will appear more fully from the following description.

### BRIEF DESCRIPTION OF DRAWINGS

FIG. 1 is a cross-sectional view of a semiconductor device according to Embodiment 1.

FIG. 2 is a plan view of the semiconductor device according to Embodiment 1.

FIG. 3 is a cross-sectional view of a semiconductor device according to Embodiment 2.

FIG. 4 is a cross-sectional view of a semiconductor device according to Embodiment 3.

### DESCRIPTION OF EMBODIMENTS

Semiconductor devices and methods for manufacturing the semiconductor devices according to each embodiment will be described with reference to the drawings. The same reference numerals may be assigned to the same or corresponding components, and repeated description may be omitted.

### Embodiment 1

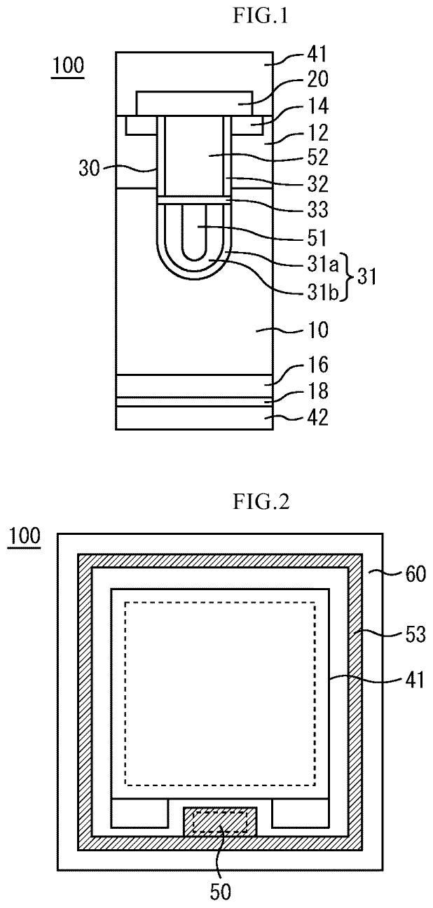

FIG. 1 is a cross-sectional view of a semiconductor device 100 according to Embodiment 1. The semiconductor device 100 is, for example, an IGBT. The semiconductor device 100 includes a semiconductor substrate 10. The semiconductor substrate 10 has an upper surface and a rear surface opposite to the upper surface, and a trench 30 is formed on the upper surface. The semiconductor substrate 10 is, for example, a silicon substrate. Not limited to this, the semiconductor substrate 10 may be formed of a wide bandgap semiconductor. The wide bandgap semiconductor is silicon carbide, a gallium nitride-based material, or diamond. A main electrode 41, which is, for example, an emitter electrode, is provided on the upper surface of the semiconductor substrate 10. A main electrode 42, which is, for example, a collector electrode, is provided on the rear surface of the semiconductor substrate 10.

FIG. 2 is a plan view of the semiconductor device 100 according to Embodiment 1. The semiconductor device 100 includes an outer peripheral region 60 corresponding to a termination region at a chip end, and a gate wiring 53 inside the outer peripheral region 60. An emitter pad, which is the main electrode 41, is provided inside the gate wiring 53. A region where the main electrode 41 is provided serves as a cell region. One or more trenches 30 are provided in a cell region. In addition, a gate pad 50 connected to the gate wiring 53 is provided between the main electrode 41 and the outer peripheral region 60.

Returning to FIG. 1, each semiconductor layer will be described. Note that, as for conductivity types of the semiconductor layer, the description will be made assuming that a first conductivity type is an n-type and a second conductivity type is a p-type; however, the first conductivity type may be a p-type, and the second conductivity type may be an n-type. The semiconductor substrate 10 is, for example, n-type. A p-type semiconductor region 12, which is a base region, is provided on the upper surface side of the semiconductor substrate 10. An n-type semiconductor region 14, which is an emitter region, is provided on the upper surface side of the semiconductor region 12. The semiconductor region 14 is selectively provided on the uppermost surface of the semiconductor substrate 10.

An n-type semiconductor region 16, which is a buffer region, is provided on the rear surface side of the semiconductor substrate 10. A p-type semiconductor region 18, which is a collector region, is provided on the rear surface side of the semiconductor region 16. The semiconductor region 18 is provided on the lowermost surface of the semiconductor substrate 10.

The trench 30 penetrates the semiconductor region 14 and the semiconductor region 12 from the upper surface of the semiconductor substrate 10, and extends to the semiconductor substrate 10, that is, a drift layer. A gate electrode 51 and a gate electrode 52 on the gate electrode 51 are provided inside the trench 30. An insulating film 31 is provided between the gate electrode 51 and the side wall of the trench 30 in the direction parallel to the upper surface of the semiconductor substrate 10. An insulating film 32 is provided between the gate electrode 52 and the side wall of the trench 30 in the direction parallel to the upper surface of the semiconductor substrate 10. In the direction from the upper surface toward the rear surface of the semiconductor substrate 10, the gate electrode 51 and the gate electrode 52 are separated and insulated by a insulating film 33. The insulating films 31, 32, and 33 are, for example, silicon oxide films.

The insulating film 31 includes an outer insulating film 31a in contact with the semiconductor substrate 10 and an inner insulating film 31b in contact with the gate electrode 51. The insulating film 32 is in contact with the semiconductor region 12. The insulating film 33 is disposed below the lower end of the semiconductor region 14. The main electrode 41 is provided on the gate electrode 52 with an interlayer film 20 interposed therebetween.

Next, each layer will be described in more detail. The main electrodes 41 and 42 are made of a metal containing at least one of, for example, aluminum (Al), tungsten (W), titanium (Ti), nickel (Ni), gold (Au), and silver (Ag). It is desirable that the main electrode 41 contains a metal having a coefficient of linear expansion of less than 24 mm/(m·K). It is further preferable that the main electrode 41 contains a metal having a coefficient of linear expansion of less than 5 μm/(m·K). Specifically, the main electrode 41 preferably contains tungsten or titanium, which have a low coefficient of linear expansion. The coefficient of linear expansion of tungsten is 4.5 μm/(m·K). Warping can be suppressed by depositing a metal having a coefficient of linear expansion close to that of silicon (Si) to form an electrode.

The interlayer film 20 is arranged so as to separate the trench 30 and the main electrode 41. The interlayer film 20 is made of, for example, a material containing silicon oxide film (SiO2) as a main component.

A impurity concentration of the semiconductor substrate 10 is determined according to a breakdown voltage required for the power semiconductor device, the thickness of the power semiconductor device, and the like. The semiconductor substrate 10 has the impurity concentration of, for example, about 1×10¹² to 1×10¹⁵ cm⁻³.

The p-type semiconductor region 18 is in contact with the main electrode 42. The semiconductor region 18 is formed, for example, by doping silicon with at least one dopant such as boron (B) one or more times. Note that silicon as the material of the semiconductor substrate 10 and boron as the dopant are merely examples and are not limited thereto. The depth of the semiconductor region 18 from the rear surface of the semiconductor substrate 10 is, for example, 2 μm or less.

The n-type semiconductor region 16 is formed, for example, by doping silicon with at least one dopant such as phosphorus (P) one or more times. Phosphorus as the dopant is an example and is not limited thereto. The depth of the semiconductor region 16 from the rear surface of the semiconductor substrate 10 is, for example, 30 μm or less.

The side surface of the n-type semiconductor region 14 is in contact with the trench 30, and a part of the upper surface is in contact with the main electrode 41. The semiconductor region 14 is formed, for example, by doping silicon with at least one dopant such as phosphorus one or more times. Phosphorus as the dopant is an example and is not limited thereto. A impurity concentration of the semiconductor region 14 is, for example, about 1×10¹⁷ to 1×10²⁰ cm⁻³. The depth of the semiconductor region 14 from the upper surface of the semiconductor substrate 10 is, for example, 2 μm or less.

The side surface of the p-type semiconductor region 12 is in contact with the trench 30. The semiconductor region 12 is formed, for example, by doping silicon with a dopant such as boron. Boron as the dopant is an example and is not limited thereto. The impurity concentration of the semiconductor region 12 is about 1×10¹² to 1×10¹⁹ cm⁻³. The depth of the semiconductor region 12 from the upper surface of the semiconductor substrate 10 is, for example, 10 μm or less. The depth of the trench 30 is, for example, 10 μm or less, and is deeper than the semiconductor region 12.

In at least one of the plurality of trenches 30, the gate electrode 51 is electrically connected to the main electrode 41. The gate electrode 51 is made of polycrystalline silicon or amorphous silicon containing an n-type or p-type dopant. The gate electrode 51 is preferably formed of amorphous silicon. The material of the gate electrode 51 is not limited.

The gate electrode 52 is insulated from the main electrode 41 by the interlayer film 20. In at least one of the plurality of trenches 30, the gate electrode 52 is electrically connected to the gate pad 50. The gate electrode 52 is made of polycrystalline silicon or amorphous silicon containing an n-type or p-type dopant.

It should be noted that, in at least one or more of the plurality of trenches 30, the gate electrode 51 may be electrically connected to the gate pad 50, and the gate electrode 52 may be electrically connected to the main electrode 41. This makes it possible to control the gate-collector capacitance, suppress the on-resistance, and increase the switching speed. In addition, in the plurality of trenches 30, the plurality of gate electrodes 51 may include a gate electrode electrically connected to the main electrode 41 and a gate electrode electrically connected to the gate pad 50, and the plurality of gate electrodes 52 may be electrically connected to the gate pad 50. In addition, in the plurality of trenches 30, the plurality of gate electrodes 51 may be electrically connected to the main electrode 41, and the plurality of gate electrodes 52 may include a gate electrode electrically connected to the main electrode 41 and a gate electrode electrically connected to the gate pad 50. Furthermore, in the plurality of trenches 30, the plurality of gate electrodes 51 may include a gate electrode electrically connected to the main electrode 41 and a gate electrode electrically connected to the gate pad 50, and the plurality of gate electrodes 52 may include a gate electrode electrically connected to the main electrode 41. That is, at least one of the plurality of gate electrodes 52 only needs to be electrically connected to the main electrode 41.

The gate electrode 51 and the semiconductor substrate 10 are separated and insulated by the insulating film 31. The insulating film 31 is formed of two different silicon insulating films: the outer insulating film 31a and the inner insulating film 31b. Both the outer insulating film 31a and the inner insulating film 31b are composed of a material containing a silicon oxide film as a main component.

The inner insulating film 31b has interface states. The density of interface states of the inner insulating film 31b is higher than the density of interface states of the outer insulating film 31a. Specifically, the density of interface states between the inner insulating film 31b and the gate electrode 51 may be higher than the density of interface states between the outer insulating film 31a and the semiconductor substrate 10. The outer insulating film 31a and the inner insulating film 31b are, for example, silicon oxide films with different degrees of compactness. The density of interface states of the inner insulating film 31b may be higher than the density of interface states of the insulating film 32 or the insulating film 33.

The insulating film 31 also has a first portion provided between the gate electrode 51 and the sidewall of the trench 30 in the direction parallel to the upper surface of the semiconductor substrate 10, and a second portion provided under the gate electrode 51. The second portion, that is, the bottom of the insulating film 31, is thinner than the first portion, that is, the side of the insulating film 31. Generally, the horizontal thickness of an insulating film significantly affects warpage. When viewed in the horizontal direction, the insulating film at the bottom is much thicker than the insulating film at the side. In contrast, by making the bottom of the insulating film 31 as thin as possible in the vertical direction from the upper surface to the rear surface of the semiconductor substrate 10, the region where the insulating film 31 is thick in the horizontal direction can be narrowed. Therefore, the influence of warpage can be reduced.

The insulating film 33 is arranged so as to separate the gate electrodes 51 and 52 and electrically insulate them. The insulating film 33 is made of, for example, a material containing a silicon oxide film as a main component. It is desirable that the insulating film 33 is a silicon insulating film containing nitrogen or a silicon oxide film containing nitrogen. By using a silicon insulating film containing nitrogen, which has a high dielectric constant, for the insulating film 33, the thickness can be reduced. Furthermore, since a dense film can be formed as the insulating film 33, the leakage current between the gate electrodes 51 and 52 can be suppressed. In addition, it is possible to suppress impurity diffusion from the gate electrodes 51 and 52, and to improve hot carrier resistance.

The insulating film 32 separates the gate electrode 52 from the semiconductor region 14 and the semiconductor region 12, and electrically insulates them. The insulating film 32 is made of, for example, a material mainly composed of a silicon oxide film. The materials for the insulating films 31, 32, and 33 are not limited.

Next, a method for manufacturing the semiconductor device 100 will be described. Hereinafter, a method for manufacturing the cell region will be mainly described. The termination region may be manufactured by a well-known manufacturing method. First, the n-type semiconductor substrate 10 is prepared. Next, a p-type dopant such as boron is doped from the upper surface side of the semiconductor substrate 10 by an ion implantation apparatus, thereby forming the p-type semiconductor region 12. The semiconductor region 12 is formed by doping a dopant into the n-type semiconductor substrate 10 and then diffusing the dopant by heat treatment. The p-type dopant is doped after a mask process is performed on the upper surface of the n-type semiconductor substrate 10. Therefore, the semiconductor region 12 is selectively formed on the upper surface side of the semiconductor substrate 10.

In the mask processing, resist is first applied on the semiconductor substrate 10, and an opening is formed in a predetermined region of the resist by using a photolithography technique. Next, doping or etching is performed on the predetermined region of the semiconductor substrate 10 through the opening of the resist.

Next, an n-type dopant is selectively doped into the upper surface side of the semiconductor region 12 by mask processing, thereby forming the n-type semiconductor region 14. The n-type dopant to be implanted is, for example, arsenic or phosphorus.

Next, the trench 30 is formed by a masking process so as to penetrate the semiconductor region 14 and the semiconductor region 12 from the upper surface of the semiconductor substrate 10. However, depending on the masking process, the trench 30 may not penetrate the semiconductor region 14.

Thereafter, the semiconductor substrate 10 is heated at 900° C. or higher in an oxygen-containing atmosphere to thinly form the outer insulating film 31a on the inner wall of the trench 30. That is, the outer insulating film 31a is formed on the inner wall of the trench 30 by thermal oxidation. Next, the inner insulating film 31b is formed on the inner wall of the trench 30 by chemical vapor deposition (CVD) so as to be thicker than the outer insulating film 31a. As a result, the inner insulating film 31b is formed on the outer insulating film 31a inside the trench 30.

In CVD, a coating is generated by mutual reaction of a plurality of gases. Examples of CVD include thermal CVD, plasma CVD, and photo CVD. In thermal CVD, film formation is performed by thermal equilibrium reactions of multiple gases. In plasma CVD, the reaction temperature of the gas is lowered by utilizing a reaction promoting effect of the plasma. In photo-CVD, a photolysis effect by ultraviolet rays or laser light is utilized. In CVD, various films can be obtained by the combination of reaction gases. CVD is also widely used for forming hard films such as carbides, nitrides, and oxides.

The inner insulating film 31b is formed by CVD at 500° C. or less, and interface states exist. By forming the inner insulating film 31b at a relatively low temperature, warpage can be suppressed even if the insulating film 31 is formed thickly.

Next, n-type or p-type doped polycrystalline silicon or amorphous silicon is deposited by CVD or the like into the trench 30 in which the insulating film 31 is formed. Thereby, the gate electrode 51 is formed. The gate electrode 51 is separated from the inner wall of the trench 30 by the insulating film 31.

Next, a portion of the first insulating film 31 and a portion of the first gate electrode 51 on an upper side of the trench 30 are removed by etching. Thus, the shapes of the insulating film 31 and the gate electrode 51 in the semiconductor device 100 are formed.

Next, the semiconductor substrate 10 is heated in an atmosphere containing oxygen to form the insulating film 33 on the upper surface of the gate electrode 51. At this time, it is desirable to form the insulating film 33 in an atmosphere containing oxygen and nitrogen. Thereby, a silicon insulating film including nitrogen can be formed as the insulating film 33. The insulating film 32 may be formed at the same time as the insulating film 33. That is, the insulating films 32 and 33 may be formed by thermal oxidation. The insulating film 32 is formed above the insulating film 31 on the inner wall of the trench 30.

Then, the gate electrode 52 is formed by depositing, on the insulating film 33 inside the trench 30, polycrystalline silicon or amorphous silicon doped with an n-type or p-type dopant by CVD or the like. The gate electrode 52 is separated from the inner wall of the trench 30 by the insulating film 32.

Next, the interlayer film 20 is formed so as to cover the gate electrode 52. Thereafter, the interlayer film 20 is removed by mask processing and etching so as to expose the semiconductor regions 12, 14 while maintaining a state where the interlayer film 20 covers the gate electrode 52.

Next, the main electrode 41 is formed on the upper surface of the semiconductor substrate 10 and the interlayer film 20. The main electrode 41 is formed by depositing an Al-Si based alloy or the like by, for example, sputtering, vapor deposition, or the like. As described above, it is desirable to form the main electrode 41 by depositing tungsten or titanium.

The main electrode 41 may be formed by plating. A metal film may be formed by electroless plating or electrolytic plating on a metal film formed by sputtering, vapor deposition, or the like. At this time, it is desirable to form a plating layer having a coefficient of linear expansion of less than 24 μm/(m·K). According to plating, a metal film thicker than that formed by vapor deposition can be easily formed. Therefore, heat resistance can be improved by increasing the heat capacity of the main electrode 41. In addition, the effect of reducing warpage can be obtained.

It should be noted that, after forming the main electrode 41 with an aluminum-silicon alloy or the like, a nickel alloy may be further formed by plating, for example. In this case, the plating process for forming the nickel alloy may be performed after processing the rear surface side of the semiconductor substrate 10.

Next, the rear surface side of the semiconductor substrate 10 is formed. Prior to the rear surface side doping, the rear surface of the semiconductor substrate 10 is ground over the entire wafer, and the semiconductor substrate 10 is thinned to a predetermined thickness. The thickness of the semiconductor substrate 10 after grinding is determined by the set breakdown voltage and the resistivity of the semiconductor substrate 10. The semiconductor substrate 10 has the thickness of, for example, 60 μm to 400 μm.

Thereafter, at least one n-type dopant such as phosphorus is doped one or more times into the semiconductor substrate 10 from the rear surface side by using an ion implanter to form the semiconductor region 16. For example, the semiconductor region 16 may be formed by doping phosphorus twice and doping protons three times. Protons can be doped to a deep position from the rear surface of the semiconductor substrate 10 with a relatively low acceleration energy. In addition, by changing the acceleration energy, the depth at which the protons are doped can be changed relatively easily. Therefore, when the semiconductor region 16 is formed of protons, doping may be performed one or more times while changing the acceleration energy. This makes it possible to form the thicker semiconductor region 16 than when the semiconductor region 16 is formed of phosphorus.

Also, phosphorus is less likely to diffuse than protons. Therefore, phosphorus allows high-temperature heat treatment and has a high activation rate as an n-type dopant. Therefore, even with the thinned semiconductor substrate 10, forming the semiconductor region 16 with phosphorus can suppress punch-through of the depletion layer. To further reduce the thickness of the semiconductor substrate 10, it is desirable to dope both phosphorus and protons to form a semiconductor region 16 in which the protons are doped deeper than the phosphorus.

Furthermore, a p-type dopant such as boron is doped from the rear surface side of the semiconductor substrate 10 to form a semiconductor region 18. Furthermore, an annealing step is performed on the rear surface side of the semiconductor substrate 10 using, for example, a laser annealing apparatus. As a result, the semiconductor region 18 is formed. At this time, the phosphorus in the semiconductor region 16, which is doped relatively shallow from the rear surface of the semiconductor substrate 10, is also activated simultaneously. This annealing step is performed after the step of forming the semiconductor region 16 and the step of forming the semiconductor region 18.

Note that protons in the semiconductor region 16 are activated at a relatively low temperature, such as 350° C. to 500° C. Therefore, after doping with protons, it is necessary to be careful to ensure that the entire semiconductor substrate does not reach a temperature higher than 500° C. in steps other than the step for activating the protons. Furthermore, the activation can also be controlled by the annealing time. For example, activation can be promoted and the diffusion depth can be adjusted by adjusting the annealing time, such as 2 hours at 350° C., 1 hour at 450° C., and 30 minutes at 500° C.

Next, the main electrode 42 is formed on the rear surface of the semiconductor substrate 10. The main electrode 42 may be formed by depositing an Al-Si alloy, titanium, or the like by, for example, sputtering, vapor deposition, or the like. The main electrode 42 may be formed by depositing a plurality of metals such as an aluminum-silicon alloy, titanium, nickel, and gold. Furthermore, a metal film may be further formed on a metal film formed by sputtering, vapor deposition, or the like by electroless plating, electrolytic plating, or the like.

Finally, the semiconductor device 100 can be manufactured by dicing it into individual pieces.

The warpage tendency of the semiconductor device 100 can be calculated by S=((t_{D}·W)/ΔW·n)·(1−cos(ΔW·n/2·t_{D}))·t_{D} is the thickness of the semiconductor device 100, W is a width of the semiconductor device 100 at room temperature, and n is the number of trenches 30 existing in stripes in the semiconductor device 100, or the number of repetition patterns of cells. Also, ΔW=(T_{P}−T_{R})·(k_{Si}−kₒₓ)·t_{ox·}T_{P} is a formation temperature of the insulating film 31, T_{R} is a room temperature, k_{Si} is a linear expansion coefficient of the semiconductor substrate 10, kₒₓ is a linear expansion coefficient of the insulating film 31, and tₒₓ is the thickness of the insulating film 31.

From this equation, it is understood that the risk of warpage increases as the size of the semiconductor device 100 increases. Also, it is understood that warpage can be suppressed by lowering the formation temperature of the insulating film 31. Furthermore, it is understood that warpage can be suppressed as the coefficient of linear expansion of the insulating film 31 is closer to the coefficient of linear expansion of the semiconductor substrate 10.

In the semiconductor device 100 according to the present disclosure, chemical vapor deposition, which allows film formation at a lower temperature than thermal oxidation, is employed as a method for forming the inner insulating film 31b. Therefore, expansion due to thermal history can be suppressed, and warpage of the semiconductor device 100 can be suppressed. In particular, it is possible to suppress warpage of the singulated semiconductor device 100 and improve yield during assembly.

Further, the density of interface states of the inner insulating film 31b formed by chemical vapor deposition is higher than the density of interface states of the outer insulating film 31a. As described above, the silicon oxide film formed by chemical vapor deposition has a problem of forming interface states, but the region of the lower gate electrode 51 of the trench 30 is not a region for forming a channel. Therefore, in the present embodiment, the influence of interface states can be suppressed.

It should be noted that interface states are formed both at the interface between the inner insulating film 31b and the gate electrode 51, and at the interface between the inner insulating film 31b and the outer insulating film 31a, but are mainly formed at the interface on the gate electrode 51 side. In addition, interface states are also slightly formed in the outer insulating film 31a formed by thermal oxidation, but are fewer than the interface states of the inner insulating film 31b.

The presence of the outer insulating film 31a can suppress the influence of interface states on the formation of an inversion layer between the outer insulating film 31a and the semiconductor substrate 10 when connecting the gate electrode 51 to the gate pad 50.

The above-described modifications can be applied as appropriate to the semiconductor device according to the following embodiments. Since the semiconductor device according to the following embodiment has many points in common with Embodiment 1, the description will focus on the differences from Embodiment 1.

### Embodiment 2.

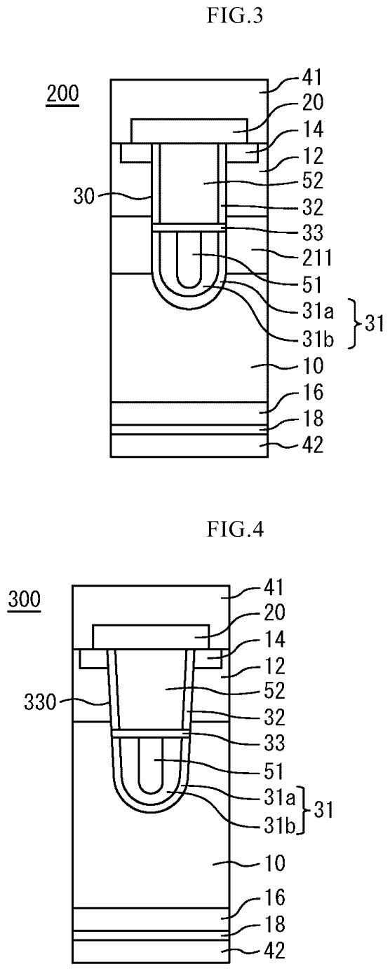

FIG. 3 is a cross-sectional view of a semiconductor device 200 according to Embodiment 2. The semiconductor device 200 differs from the semiconductor device 100 in that an n-type semiconductor region 211, which is a charge storage region, is provided on the upper surface side of the semiconductor substrate 10. The semiconductor region 211 is formed at a deeper position from the upper surface of the semiconductor substrate 10 than the semiconductor region 12. The trench 30 penetrates the semiconductor region 211 and extends to the drift layer. The semiconductor region 211 and the gate electrode 51 are separated by the insulating film 31 and are electrically insulated.

The semiconductor region 211 is formed by doping, for example, silicon with a dopant such as phosphorus. Phosphorus as the dopant is an example and is not limited thereto. The impurity concentration of the semiconductor region 211 is, for example, about 1×10¹³ to 1×10¹⁸ cm⁻³, and is, for example, higher than that of the drift layer. The depth from the upper surface of the semiconductor substrate 10 is, for example, 10 μm or less.

Next, a method for manufacturing the semiconductor device 200 will be described. First, the semiconductor substrate 10 is prepared, and an n-type dopant such as phosphorus is doped from the upper surface side of the semiconductor substrate 10 by an ion implantation apparatus to form the semiconductor region 211. Further, the semiconductor region 12 is formed by doping a p-type dopant such as boron from the upper surface side of the semiconductor substrate 10 with an ion implantation apparatus. The semiconductor region 211 and the semiconductor region 12 are formed by diffusing the dopant by heat treatment after doping. The n-type dopant and the p-type dopant are doped after a mask process is performed on the upper surface of the semiconductor substrate 10. Therefore, the semiconductor regions 211 and 12 are selectively formed on the upper surface side of the semiconductor substrate 10.

Next, the semiconductor region 14 is formed in the same manner as in Embodiment 1. Thereafter, the trench 30 is formed by a masking process so as to penetrate the semiconductor regions 14, 12, and 211 from the upper surface side of the semiconductor substrate 10. The subsequent steps can apply the manufacturing method for Embodiment 1.

The semiconductor region 211 is a layer for accumulating electric charge. By providing the semiconductor region 211, it is possible to prevent holes supplied from the rear surface from escaping to the emitter electrode when the IGBT is conducting. Thereby, the carrier distribution is improved, the on-voltage of the IGBT can be reduced, and the switching loss can be improved.

### Embodiment 3

FIG. 4 is a cross-sectional view of a semiconductor device 300 according to Embodiment 3. This embodiment differs from Embodiment 1 in that the sidewall of a trench 330 is inclined with respect to the direction from the upper surface to the rear surface of the semiconductor substrate 10. That is, an angle formed by the sidewall of the trench 30 and the upper surface of the semiconductor substrate 10 is smaller than 90 degrees. This can improve the embedding property of the oxide film into the trench 30. Therefore, a more uniform oxide film can be formed.

The technical features described in each embodiment may be combined and used as appropriate.

Hereinafter, various aspects of the present disclosure will be collectively described as appendixes.

### Appendix 1

### A Semiconductor Device Comprising:

a semiconductor substrate having an upper surface and a rear surface opposite to the upper surface, a trench being formed in the upper surface;
a first main electrode provided on the upper surface of the semiconductor substrate;
a second main electrode provided on the rear surface of the semiconductor substrate;
a first gate electrode provided inside the trench;
a first insulating film provided between the first gate electrode and a sidewall of the trench in a direction parallel to the upper surface of the semiconductor substrate;
a second gate electrode provided on the first gate electrode inside the trench;
a second insulating film provided between the second gate electrode and the sidewall of the trench in the direction parallel to the upper surface of the semiconductor substrate; and
a third insulating film separating the first gate electrode and the second gate electrode in a direction from the upper surface to the rear surface of the semiconductor substrate, wherein
the first insulating film includes an outer insulating film in contact with the semiconductor substrate, and an inner insulating film in contact with the first gate electrode, and
a density of interface states of the inner insulating film is higher than a density of interface states of the outer insulating film.

### Appendix 2

The semiconductor device according to appendix 1, wherein the outer insulating film and the inner insulating film are silicon oxide films having different degrees of compactness.

### Appendix 3

The semiconductor device according to appendix 1 or 2, wherein the semiconductor substrate is a first conductivity type and has a base region of a second conductivity type on the upper surface side,
the second insulating film is in contact with the base region, and
the third insulating film is arranged below a lower end of the base region.

### Appendix 4

The semiconductor device according to appendix 3, wherein the semiconductor substrate has a charge storage region of the first conductivity type on the upper surface side, and
the charge storage region is formed at a position deeper from the upper surface of the semiconductor substrate than the base region.

### Appendix 5

The semiconductor device according to any one of appendixes 1 to 4, wherein the first insulating film includes:
a first portion provided between the first gate electrode and the sidewall of the trench in the direction parallel to the upper surface of the semiconductor substrate; and
a second portion provided under the first gate electrode, and
the second portion is thinner than the first portion.

### Appendix 6

The semiconductor device according to any one of appendixes 1 to 5, wherein the sidewall of the trench is inclined with respect to the direction from the upper surface to the rear surface of the semiconductor substrate.

### Appendix 7

The semiconductor device according to any one of appendixes 1 to 6, wherein the first gate electrode is electrically connected to a gate pad, and
the second gate electrode is electrically connected to the first main electrode.

### Appendix 8

The semiconductor device according to any one of appendixes 1 to 6, wherein the first gate electrode is electrically connected to the first main electrode, and
the second gate electrode is electrically connected to a gate pad.

### Appendix 9

The semiconductor device according to any one of appendixes 1 to 6, wherein a plurality of the trenches are formed in the semiconductor substrate,
a plurality of the first gate electrodes of the plurality of trenches include a gate electrode electrically connected to the first main electrode and a gate electrode electrically connected to a gate pad, and
a plurality of the second gate electrodes of the plurality of trenches are electrically connected to the gate pad.

### Appendix 10

The semiconductor device according to any one of appendixes 1 to 6, wherein a plurality of the trenches are formed in the semiconductor substrate,
a plurality of the first gate electrodes of the plurality of trenches are electrically connected to the first main electrode, and
a plurality of the second gate electrodes of the plurality of trenches include a gate electrode electrically connected to the first main electrode, and a gate electrode electrically connected to a gate pad.

### Appendix 11

The semiconductor device according to any one of appendixes 1 to 6, wherein a plurality of the trenches are formed in the semiconductor substrate,
a plurality of the first gate electrodes of the plurality of trenches include a gate electrode electrically connected to the first main electrode, and a gate electrode electrically connected to a gate pad, and
a plurality of the second gate electrodes of the plurality of trenches include a gate electrode electrically connected to the first main electrode.

### Appendix 12

The semiconductor device according to any one of appendixes 1 to 11, wherein the third insulating film is a silicon insulating film containing nitrogen.

### Appendix 13

The semiconductor device according to any one of appendixes 1 to 12, wherein the first main electrode includes a metal having a coefficient of linear expansion of less than 24 μm/(m·K).

### Appendix 14)

The semiconductor device according to appendix 13, wherein the first main electrode includes a metal having a coefficient of linear expansion of less than 5 μm/(m·K).

### Appendix 15)

The semiconductor device according to any one of appendixes 1 to 14, wherein the first main electrode includes tungsten.

### Appendix 16)

The semiconductor device according to any one of appendixes 1 to 15, wherein the first gate electrode is made with amorphous silicon.

### Appendix 17

The semiconductor device according to any one of appendixes 1 to 16, wherein the semiconductor substrate is made with a wide bandgap semiconductor.

### Appendix 18

The semiconductor device according to appendix 17, wherein the wide bandgap semiconductor is silicon carbide, a gallium nitride-based material, or diamond.

### Appendix 19

A method for manufacturing a semiconductor device, the method comprising:
forming a trench in an upper surface of a semiconductor substrate having the upper surface and a rear surface opposite to the upper surface;
forming an outer insulating film on an inner wall of the trench by thermal oxidation;
forming an inner insulating film on the outer insulating film by chemical vapor deposition at 500° C. or less inside the trench;
forming a first gate electrode in the trench such that the first gate electrode is separated from the inner wall of the trench by a first insulating film including the outer insulating film and the inner insulating film;
after removing a portion of the first insulating film and a portion of the first gate electrode on an upper side of the trench, forming a second insulating film on the inner wall of the trench above the first insulating film and forming a third insulating film on the first gate electrode;
forming a second gate electrode on the third insulating film inside the trench such that the second gate electrode is separated from the inner wall of the trench by the second insulating film;
forming a first main electrode on the upper surface of the semiconductor substrate; and
forming a second main electrode on the rear surface of the semiconductor substrate.

### Appendix 20

The method for manufacturing a semiconductor device according to appendix 19, wherein the thermal oxidation is performed at 900° C. or higher.

### Appendix 21

The method for manufacturing a semiconductor device according to appendix 19 or 20, wherein the first main electrode is formed by plating.

In the semiconductor device according to the present disclosure, the density of interface states of the inner insulating film is higher than the density of interface states of the outer insulating film. At this time, chemical vapor deposition, which enables film formation at a lower temperature than thermal oxidation, can be employed as a method for forming the inner insulating film. Therefore, warpage of the semiconductor device can be suppressed.

In the method for manufacturing the semiconductor device according to the present disclosure, the inner insulating film is formed by chemical vapor deposition. Therefore, warpage of the semiconductor device can be suppressed.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2025-041067, filed on Mar. 14, 2025 including specification, claims, drawings and summary, on which the Convention priority of the present application is based, are incorporated herein by reference in its entirety.

1. A semiconductor device comprising:
a semiconductor substrate having an upper surface and a rear surface opposite to the upper surface, a trench being formed in the upper surface;
a first main electrode provided on the upper surface of the semiconductor substrate;
a second main electrode provided on the rear surface of the semiconductor substrate;
a first gate electrode provided inside the trench;
a first insulating film provided between the first gate electrode and a sidewall of the trench in a direction parallel to the upper surface of the semiconductor substrate;
a second gate electrode provided on the first gate electrode inside the trench;
a second insulating film provided between the second gate electrode and the sidewall of the trench in the direction parallel to the upper surface of the semiconductor substrate; and
a third insulating film separating the first gate electrode and the second gate electrode in a direction from the upper surface to the rear surface of the semiconductor substrate, wherein
the first insulating film includes an outer insulating film in contact with the semiconductor substrate, and an inner insulating film in contact with the first gate electrode, and
a density of interface states of the inner insulating film is higher than a density of interface states of the outer insulating film.

2. The semiconductor device according to claim 1, wherein the outer insulating film and the inner insulating film are silicon oxide films having different degrees of compactness.

3. The semiconductor device according to claim 1, wherein the semiconductor substrate is a first conductivity type and has a base region of a second conductivity type on the upper surface side,
the second insulating film is in contact with the base region, and
the third insulating film is arranged below a lower end of the base region.

4. The semiconductor device according to claim 3, wherein the semiconductor substrate has a charge storage region of the first conductivity type on the upper surface side, and
the charge storage region is formed at a position deeper from the upper surface of the semiconductor substrate than the base region.

5. The semiconductor device according to claim 1, wherein the first insulating film includes:
a first portion provided between the first gate electrode and the sidewall of the trench in the direction parallel to the upper surface of the semiconductor substrate; and
a second portion provided under the first gate electrode, and
the second portion is thinner than the first portion.

6. The semiconductor device according to claim 1, wherein the sidewall of the trench is inclined with respect to the direction from the upper surface to the rear surface of the semiconductor substrate.

7. The semiconductor device according to claim 1, wherein the first gate electrode is electrically connected to a gate pad, and
the second gate electrode is electrically connected to the first main electrode.

8. The semiconductor device according to claim 1, wherein the first gate electrode is electrically connected to the first main electrode, and
the second gate electrode is electrically connected to a gate pad.

9. The semiconductor device according to claim 1, wherein a plurality of the trenches are formed in the semiconductor substrate,
a plurality of the first gate electrodes of the plurality of trenches include a gate electrode electrically connected to the first main electrode and a gate electrode electrically connected to a gate pad, and
a plurality of the second gate electrodes of the plurality of trenches are electrically connected to the gate pad.

10. The semiconductor device according to claim 1, wherein a plurality of the trenches are formed in the semiconductor substrate,
a plurality of the first gate electrodes of the plurality of trenches are electrically connected to the first main electrode, and
a plurality of the second gate electrodes of the plurality of trenches include a gate electrode electrically connected to the first main electrode, and a gate electrode electrically connected to a gate pad.

11. The semiconductor device according to claim 1, wherein a plurality of the trenches are formed in the semiconductor substrate,
a plurality of the first gate electrodes of the plurality of trenches include a gate electrode electrically connected to the first main electrode, and a gate electrode electrically connected to a gate pad, and
a plurality of the second gate electrodes of the plurality of trenches include a gate electrode electrically connected to the first main electrode.

12. The semiconductor device according to claim 1, wherein the third insulating film is a silicon insulating film containing nitrogen.

13. The semiconductor device according to claim 1, wherein the first main electrode includes a metal having a coefficient of linear expansion of less than 24 μm/(m·K).

14. The semiconductor device according to claim 13, wherein the first main electrode includes a metal having a coefficient of linear expansion of less than 5 μm/(m·K).

15. The semiconductor device according to claim 1, wherein the first main electrode includes tungsten.

16. The semiconductor device according to claim 1, wherein the first gate electrode is made with amorphous silicon.

17. The semiconductor device according to claim 1, wherein the semiconductor substrate is made with a wide bandgap semiconductor.

18. The semiconductor device according to claim 17, wherein the wide bandgap semiconductor is silicon carbide, a gallium nitride-based material, or diamond.

19. A method for manufacturing a semiconductor device, the method comprising:
forming a trench in an upper surface of a semiconductor substrate having the upper surface and a rear surface opposite to the upper surface;
forming an outer insulating film on an inner wall of the trench by thermal oxidation;
forming an inner insulating film on the outer insulating film by chemical vapor deposition at 500° C. or less inside the trench;
forming a first gate electrode in the trench such that the first gate electrode is separated from the inner wall of the trench by a first insulating film including the outer insulating film and the inner insulating film;
after removing a portion of the first insulating film and a portion of the first gate electrode on an upper side of the trench, forming a second insulating film on the inner wall of the trench above the first insulating film and forming a third insulating film on the first gate electrode;
forming a second gate electrode on the third insulating film inside the trench such that the second gate electrode is separated from the inner wall of the trench by the second insulating film;
forming a first main electrode on the upper surface of the semiconductor substrate; and
forming a second main electrode on the rear surface of the semiconductor substrate.

20. The method for manufacturing a semiconductor device according to claim 19, wherein the thermal oxidation is performed at 900° C. or higher.

21. The method for manufacturing a semiconductor device according to claim 19, wherein the first main electrode is formed by plating.
